(19) United States
(12) Patent Application Publication
(10) Pub. No.: US 2009/0183833 A1
(43) Pub. Date: Jul. 23, 2009

(54) PLASMA PROCESSING APPARATUS

(75) Inventor: Do-Hyeong KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/414,443

(22) Filed: Mar. 30, 2009

Related U.S. Application Data
(62) Division of application No. 11/270,704, filed on Nov. 8, 2005.

(30) Foreign Application Priority Data
Nov. 12, 2004 (KR) 2004-0092685

(51) Int. Cl. C23F 1/08; C23C 16/54

(52) U.S. Cl. 156/345.33; 118/723 E

(57) ABSTRACT

A plasma processing apparatus comprising: a process chamber for defining a plasma processing space in which a substrate holder for mounting a substrate thereon is installed; a plasma chamber in communication with an upper portion of the process chamber to generate and inject plasma into the plasma processing space such that the substrate is processed; a screen interposed between the process chamber and the plasma chamber to block plasma ions from being injected from the plasma chamber; and an ion trap for protecting the surface of the substrate from damage due to the injected plasma ion.

### CROSS REFERENCE TO RELATED APPLICATION

This application is a Divisional of U.S. patent application Ser. No. 11/270,704, filed on Nov. 8, 2005, now pending, which claims priority under 35 U.S.C. § 119 from Korean Patent Application No. 2004-92685, filed on Nov. 12, 2004, in the Korean Intellectual Property Office, the entire contents of which are hereby incorporated by reference

### BACKGROUND OF THE INVENTION

1. Field of the Invention

The present invention relates to a plasma processing apparatus and more particularly to an inductively coupled plasma (ICP) processing apparatus.

2. Description of the Related Art

Recently, a low pressure and low temperature plasma technology has been widely used in the manufacture of semiconductor devices and flat display panels. The Plasma technology is used to etch or deposit certain materials on the surfaces of wafers for semiconductor devices or liquid crystal display (LCD) panels. Particularly, in an etching or thin film deposition process for manufacturing highly integrated semiconductor devices, the usage of plasma equipment has increased.

The most important factors in the development of the plasma equipment for semiconductor manufacturing processes are the capability of operating large substrates and the capability of performing highly integrated device fabricating processes in order to enhance production yields. Specifically, in accordance with increase in wafer size from 200 mm to 300 mm, uniformity of wafer treatment processes and a high plasma density have become very important. Various types of plasma equipment have been used for the conventional semiconductor manufacturing processes. For example, the types of plasma equipment can include a capacitive coupled plasma (CCP) type, an electron cyclotron resonance (ECR) type, an inductively coupled plasma (ICP) type, and a hybrid type, that is, a combination of two or more of the aforementioned types. Among the types of plasma equipment, the ICP equipment is considered to be the best equipment for the 300 mm large-size wafers because the ICP equipment can generate a high density and high uniformity plasma with a simpler structure than the other types of the plasma equipment.

However, since the ICP processing apparatus increases the applied power level and maximizes the plasma density in order to maximize the usage efficiency of the plasma, the capability of performing highly integrated device fabricating processes is an excellent one. However, the increase in the power level and the maximization of the plasma density cause a problem. That is, due to the maximization of the plasma density and the increase in the power level, the ion charging level also increases. Accordingly, the degradation of a gate oxide film is caused and thus the reliability of the semiconductor device deteriorates (hereinafter referred to as “plasma damage”). Accordingly, various methods for overcoming the plasma damage have been suggested.

Hereinafter, examples of an ICP processing apparatus for solving the plasma damage will be described in detail.

The ICP processing apparatus can include a process chamber including a plasma processing space which is held in a vacuum state, a substrate holder which is installed in the process chamber such that a substrate, such as a wafer, is mounted thereon, a plasma chamber which is connected to the upper portion of the process chamber and in which plasma is generated, a gas supplying unit which supplies a reaction gas into the upper end of the plasma chamber, a coil antenna wounding the circumferential surface of the plasma chamber in order to generate plasma, a RF power applying unit for applying RF power to the coil antenna such that plasma is generated, and a gas distribution plate which is fixed between the process chamber and the plasma chamber and has a predetermined number of holes such that the plasma damage is reduced and plasma generated in the plasma chamber is distributed to a plurality of directions of the plasma processing space.

The ICP processing apparatus can operate as follows:

If power is applied by the RF power applying unit, the RF currents flow in the coil antenna and a magnetic field is produced within the plasma chamber according to the RF currents flowing in the coil antenna.

As the magnetic field varies as a function of time, an electrostatic field is induced within the plasma chamber. At the same time, the reaction gas is supplied into the plasma chamber and is ionized by collisions with electrons accelerated by the induced electrostatic field. This generates plasma within the plasma chamber.

The generated plasma is injected into the process chamber and chemically reacts with the surface of the substrate mounted on the substrate holder so that the substrate is subject to a desired process, e.g., etching. Meanwhile, since the conventional ICP processing apparatus includes the gas distribution plate for reducing the plasma damage between the plasma chamber and the process chamber, the generated plasma is not directly injected into the process chamber. That is, the generated plasma is injected into the process chamber through the gas distribution plate. Accordingly, the plasma damage is significantly reduced while the substrate mounted on the substrate holder is etched by the plasma.

Since the above-described plasma processing apparatus is fixed with the gas distribution plate for improving the plasma damage, it is suitable for manufacturing a previously set element. However, it is difficult to diversely correspond to an element which is not previously set since the etching ratio and the deposition ratio thereof are different.

Also, since the plasma processing apparatus as set forth above improves the plasma damage only using the gas distribution plate, the plasma damage due to the ion charge cannot be improved in the case where the plasma density and the power level of the apparatus increase.

### SUMMARY

In order to solve the aforementioned problems, the present invention provides a plasma processing apparatus which can correspond to the manufacture of various elements while improving the plasma damage.

The present invention also provides a plasma processing apparatus which can control an ion charging level such that the plasma damage is more improved.

The present invention also provides a plasma processing apparatus which can locally control an ion charging level.

According to an aspect of the present invention, a plasma processing apparatus is provided. The apparatus comprises a process chamber for defining a plasma processing space in which a substrate holder for mounting a substrate thereon is installed. It also includes a plasma chamber in communication with an upper portion of the process chamber to generate and inject plasma into the plasma processing space such that the substrate is processed. A screen is interposed between the process chamber and the plasma chamber to block plasma ions from being injected from the plasma chamber. An ion trap is also provided for protecting the surface of the substrate from damage due to the injected plasma ion. Preferably, the ion trap means comprises a DC power applying unit connected to the screen to apply DC power to the screen. The DC power applying units apply the negative DC powers having different sizes to the regions, respectively. The screen can comprise a gas distribution plate defining a plurality of distribution holes such that the plasma injected into the process chamber is distributed in a plurality of directions of the plasma processing space, and the ion trap can comprise irregular surfaces formed in the upper and lower surfaces of the gas distribution plate such that the contact area of the plasma ion is increased.

The screen can comprise a gas distribution plate defining a plurality of distribution holes such that the plasma injected into the process chamber is distributed in various directions within the plasma processing space, and the ion trap preferably comprises at least one insulator which is provided at the gas distribution plate and divides the gas distribution plate into a plurality of regions which are insulated from each other. The ion trap can comprise irregular surfaces formed in the upper and lower surfaces of the gas distribution plate such that the contact area of the plasma ion is increased. The insulator preferably divides the gas distribution plate into a center portion, an edge portion, and a middle portion located between the center and edge portions, and the DC power applying unit comprises a first DC power applying unit for applying a negative DC power to the center portion, a second DC power applying unit for applying a negative DC power to the edge portion, and a third DC power applying unit for applying a negative DC power to the middle portion.

Another plasma processing apparatus can comprise a process chamber, a plasma chamber, and an ion trap as described above. The apparatus further preferably includes a first gas distribution plate interposed between the process chamber and the plasma chamber and defining a plurality of distribution holes such that the injected plasma is distributed to a plurality of directions within the plasma processing space, and a second gas distribution plate installed below the first gas distribution plate and defining a plurality of distribution holes such that the plasma passing through the first gas distribution plate is further distributed to a plurality of directions within the plasma processing space.

In this latter case, at least one of the first gas distribution plate and the second gas distribution plate is rotatably mounted, and the gas distribution plate which is rotatably mounted is connected to a rotating unit for rotating the rotatably mounted gas distribution plate. The ion trap means can comprise a DC power applying unit which is connected to at least one of the first gas distribution plate and the second gas distribution plate and applies negative DC power to each connected gas distribution plate. Moreover, the ion trap means preferably comprises a plurality of insulators which are provided in the gas distribution plates and which divides the gas distribution plates into a plurality of regions which are insulated from each other, respectively. Furthermore, it is preferred that at least one of the first gas distribution plate and the second gas distribution plate is rotatably mounted; and the gas distribution plate which is rotatably mounted is connected to a rotating unit for rotating the rotatably mounted gas distribution plate. Preferably, the ion trap comprises DC power applying units which are connected to the respective first and second gas distribution plates and apply negative DC powers thereto, respectively.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram of a plasma processing apparatus according to an embodiment of the present invention;

FIG. 2 is a perspective view of gas distribution plates and motors coupled thereto in the plasma processing apparatus shown in FIG. 1;

FIG. 3 is a perspective, partially-broken view of a second gas distribution plate and a DC power applying unit coupled thereto in the plasma processing unit shown in FIG. 2; and

FIG. 4 is a cross-sectional view of a gas distribution plate according to a second embodiment of the present invention.

### DETAILED DESCRIPTION

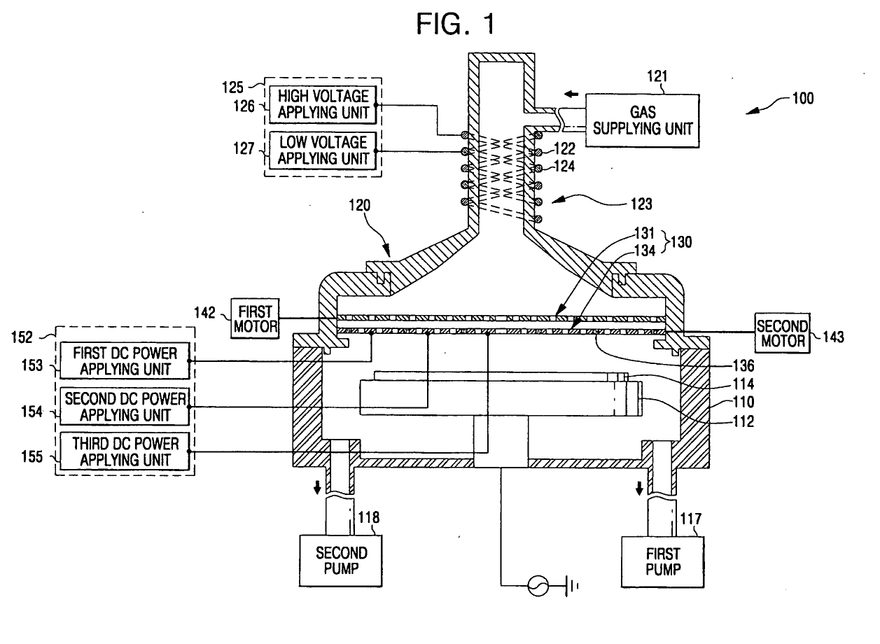

Now, exemplary embodiments of a plasma processing apparatus of the present invention will be described in detail with reference to FIGS. 1 through 4.

First, referring to FIG. 1, the plasma processing apparatus 100 according an embodiment of to the present invention includes a process chamber 110 for forming a plasma processing space, a plasma chamber 120 connected to the upper portion of the process chamber 110, and generates and injects plasma into the plasma processing space such that a substrate 114, such as a wafer, is processed. A screen is interposed between the process chamber 110 and the plasma chamber 120 and blocks plasma ions injected from the plasma chamber 120. An ion trap prevents the surface of the substrate 114 from being damaged by the plasma ions into the process chamber 110. A controller (not shown) controls the entire plasma processing apparatus.

A substrate holder 112 is installed within the process chamber 110 such that the substrate 114 which will be etched or on which materials will be deposited by plasma is mounted thereon. A pumping unit for keeping the inside of the process chamber 110 in a vacuum state suitable for the process is installed at the lower portion of the process chamber 110. Also, an electrode (not shown) is provided within the substrate holder 112. This electrode is applied with a bias power for adjusting the impact energy of the plasma ion. Accordingly, if this electrode is applied with the bias power, the plasma ion is accelerated into a substrate direction such that a thin film is deposited on the substrate 114 or a thin film which is previously deposited is etched. Also, the pumping unit includes a first pump 117 which is installed at one side of the substrate holder 112 and a second pump 118 which is installed at the other side of the substrate holder 112. The reaction byproduct generated during the process is ejected to the outside by the pumps 117 and 118 while the inside of the process chamber 110 is kept in a vacuum state suitable for the process.

The plasma chamber 120 generates plasma and injects it into the plasma processing space of the process chamber 110, and includes a gas supplying unit 121 for supplying a reaction gas into the plasma chamber 120, a coil antenna 123 wound around the circumferential surface of the plasma chamber 120 in order to generate plasma within the plasma chamber 120, and a RF power applying unit 125 for applying RF power to the coil antenna 123 such that plasma is generated within the plasma chamber 120. The gas supplying unit 121 is connected to the upper end of the plasma chamber 120 such that the reaction gas is supplied into the plasma chamber 120. The coil antenna 123 wounds around the circumferential surface of the plasma chamber 120 between the gas supplying unit 121 and the connection portion with the process chamber 110 in a spiral shape. The coil antenna 123 includes a high voltage applying coil 122 for applying a high voltage and a low voltage applying coil 124 for applying a low voltage. The RF power applying unit 125 includes a high voltage applying unit 126 for applying the high voltage to the high voltage applying coil 122 and a low voltage applying unit 127 for applying the low voltage to the low voltage applying coil 124. Accordingly, plasma is generated by applying the RF power to the coil antenna 123.

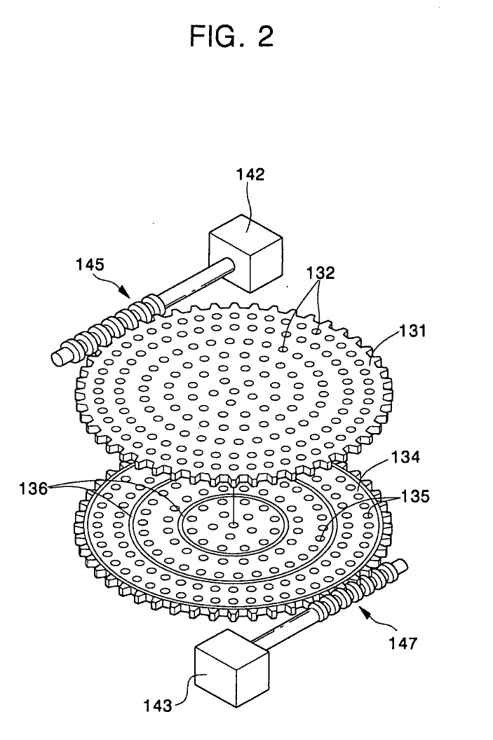

Next, the screen will be described with reference to FIG. 2. The screen may be a gas distribution plate 130 defining a plurality of distribution holes such that the plasma injected into the process chamber 110 is distributed in a plurality of directions within the plasma processing space. In this case, the gas distribution plate 130 also has a function of blocking the plasma distributed to the process chamber 110 at a certain portion to improve the plasma damage due to the ion charge, in addition to the function of distributing the plasma generated in the plasma chamber 120 in the a plurality of directions of the process chamber 110. The gas distribution plate 130 may include a first gas distribution plate 131 interposed between the process chamber 110 and the plasma chamber 120 and a second gas distribution plate 134 installed below the first gas distribution plate 131.

The first gas distribution plate 131 and the second gas distribution plate 134 are rotatable and are formed in a substantially circular plate shape. Plates 131 and 134 respectively define a plurality of distribution holes 132 and 135 penetrating therethrough in a substantially vertical direction. Accordingly, the plasma generated in the plasma chamber 120 is injected into the process chamber 110 through the distribution holes 132 and 135.

Also, rotating units for rotating the first and second gas distribution plates 131 and 134 may be further connected thereto, respectively. In this case, all or a portion of the distribution holes 132 and 135 formed in the first and second gas distribution plates 131 and 134 may be opened by the rotation of the first and second gas distribution plates 131 and 134. Accordingly, an operator can intentionally rotate both or any one of the first and second gas distribution plates 131 and 134 using the controller and the rotating units to block the plasma distributed to the process chamber 110 at a certain portion. Thus, the plasma damage due to the plasma ion charge can be improved. Meanwhile, it is preferable that the rotating units include driving units 142 and 143 for generating rotation forces, such as motors, and power delivering units 145 and 147 for delivering the rotation forces of the driving units 142 and 143 to the gas distribution plates 131 and 134, respectively, such as shafts or gears.

The ion trap means includes at least one insulator 136 which is provided at the second gas distribution plate 134 and divides the second gas distribution plate 134 into a plurality of regions which are insulated from each other, and at least two DC power applying units 152 which are connected to the regions and apply separate negative DC powers to the regions, respectively. Accordingly, the negative DC currents which have predetermined voltages flow in the second gas distribution plate 134. All or a portion of the positive ions passing through the second gas distribution plate 134 is trapped at the surface of the second gas distribution plate 134 according to the voltage sizes of the negative DC powers. At this time, the DC power applying unit 152 can apply a positive DC power. In this case, negative electrons passing through the second gas distribution plate 134 can be controlled by this positive DC power.

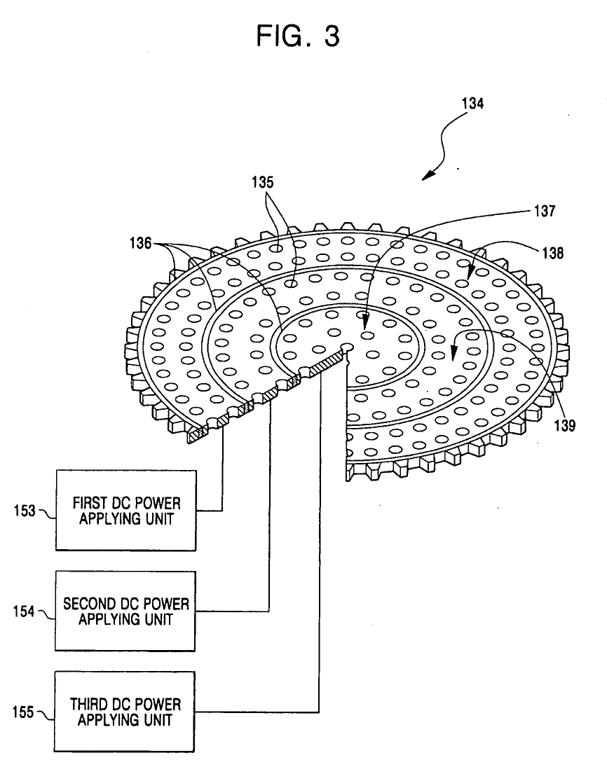

As shown in FIGS. 2 or 3, the insulator 136 can be formed in an O-ring shape which divides the circular second gas distribution plate 134 into a center portion 137, an edge portion 138, and a middle portion 139 disposed between the center portion 137 and the edge portion 138. Accordingly, the center portion 137, the edge portion 138 and the middle portion 139 are insulated with respect to each other by the insulator 136. In this case, it is preferable that the DC power applying unit 152 includes a first DC power applying unit 153 connected to the center portion 137 for applying a negative DC power to the center portion 137, a second DC power applying unit 154 connected to the edge portion 138 for applying a negative DC power to the edge portion 138, and a third DC power applying unit 155 connected to the middle portion 139 for applying a negative DC power to the middle portion 139. Accordingly, the negative DC currents flow in the center portion 137, the edge portion 138 and the middle portion 139 by the DC power applying units 153, 154 and 155, respectively, and all or a portion of the plasma ions passing through the center portion 137, the edge portion 138 and the middle portion 139 is trapped at the surfaces of the center portion 137, the edge portion 138 and the middle portion 139 by the negative DC currents, respectively.

At this time, as the voltages applied to the regions 137, 138 and 139 increase, the amount of the ions trapped in the regions 137, 138 and 139 increases. Accordingly, the operator can apply a different amount of negative DC power to the respective regions 137, 138 and 139 using the controller and the DC power applying units 153, 154 and 155. Then, the operator can locally control the amount of the trapped ions using the DC power applying units 153, 154 and 155. On the other hand, the insulator 136 and the supply of the negative DC power may be applied to the first gas distribution plate 131 in addition to the second gas distribution plate 134 (not shown). In this case, since the plasma ions passing through the gas distribution plates 131 and 134 are trapped by the plates 131, 134, the plasma damage can be more efficiently improved.

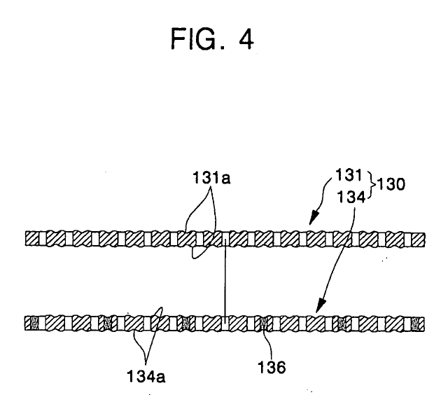

The ion trap means may further include irregular surfaces 131 a and 134a formed in the upper and lower surfaces of the gas distribution plates 131 and 134, as shown in FIG. 4. In this case, since the areas of the gas distribution plates 131 and 134 in contact with the plasma ions further increase, the plasma ions can be more trapped at the gas distribution plates 131 and 134 when applying the negative DC power thereto. Accordingly, the plasma damage can be reduced.

Hereinafter, the operation and the effect of the plasma processing apparatus 100 according to the present invention will be described.

First, if power is applied by the RF power applying unit 125, RF currents flow in the coil antenna 123. Accordingly, a magnetic field is produced within the plasma chamber 120 according to the RF currents flowing in the coil antenna 123, and then an electrostatic field is induced as the magnetic field varies with time.

At the same time, a reaction gas is supplied into the plasma chamber 120 and is ionized by collisions with electrons accelerated by the induced electrostatic field to generate plasma within the plasma chamber 120.

Next, the plasma generated in the plasma chamber 120 passes through the gas distribution plate 130 installed between the process chamber 110 and the plasma chamber 120 before being injected into the process chamber 110. At this time, the gas distribution plate 130 is rotated by the regulated by the controller and the rotating units such that all or a portion of the distribution holes 132 and 135 formed in the surface thereof is opened. In this way, a certain amount of plasma passes through the gas distribution plate 130 via the apertures of the distribution holes 131 and 135.

Also, since the negative DC currents flow in the gas distribution plate 130 of the present invention is provided by the DC power applying unit of the ion trap means, a portion of the positive ions in a certain amount of plasma is trapped at the surface of the gas distribution plate 130. Accordingly, the amount of plasma ions which pass through the gas distribution plate 130 and reach the substrate 114 of the process chamber 110 is significantly reduced. Accordingly, the substrate 114 mounted on the substrate holder 112 can be accurately processed, for example, etched, without being damaged by the plasma.

As mentioned above, since the plasma processing apparatus of the present invention can control the ion charging level using the ion trap means for trapping the plasma ions, the plasma damage which is conventionally generated by the plasma ions can be overcome. Particularly, since the ion trap according to the present invention applies different amounts of negative DC power to the regions of the gas distribution plate to trap the plasma ions, respectively, the ion charging level can be locally controlled and thus the plasma damage due to the ion charge can be more efficiently solved.

Also, since the gas distribution plate included in the plasma processing apparatus of the present invention includes a first gas distribution plate installed at the upper portion thereof and a second gas distribution plate installed at the lower portion thereof, and can be rotated by the rotating unit, the operator can adjust the aperture of the distribution holes formed in the gas distribution plate using the controller and the rotating units. According to the present invention, since the amount of the plasma which is generated in the plasma chamber and is injected into the process chamber can be adjusted, the plasma damage can be limited and the plasma processing apparatus can be used in manufacturing various elements.

While the present invention has been particularly shown and described with reference to exemplary embodiments thereof, it will be understood by those skilled in the art that various changes in form and details may be made therein without departing from the spirit and scope of the present invention as defined by the appended claims. For example, the present invention can be used in an etching apparatus, a thin film depositing apparatus, and an apparatus for supplying the reaction gas to the side of the process chamber. Particularly, in a case where the present invention is applied to the apparatus for supplying the reaction gas to the side of the process chamber, it is preferable that the screen of the present invention performs only a function of blocking the plasma ions. Accordingly, the scope of the invention is defined by the appended claims and the equivalents thereof.

What is claimed is:

1. A plasma processing apparatus comprising:
a process chamber for defining a plasma processing space in which a substrate holder for mounting a substrate thereon is installed;
a plasma chamber in communication with an upper portion of the process chamber to generate and inject plasma into the plasma processing space such that the substrate is processed;
a screen interposed between the process chamber and the plasma chamber to block plasma ions from being injected from the plasma chamber, wherein the screen comprises a gas distribution plate defining a plurality of distribution holes such that the plasma injected into the process chamber is distributed in various directions within the plasma processing space; and
an ion trap for protecting the surface of the substrate from damage due to the injected plasma ion, wherein the ion trap comprises at least one insulator which is provided at the gas distribution plate and divides the gas distribution plate into a plurality of regions which are insulated from each other and least two DC power applying units connected to the regions to apply separate negative DC power to the regions, respectively.

2. The apparatus according to claim 1, wherein the ion trap comprises a DC power applying unit connected to the screen to apply DC power to the screen.

3. The apparatus according to claim 1, wherein the DC power applying units apply negative DC power having different sizes to the regions, respectively.

4. The apparatus according to claim 1, wherein the ion trap comprises irregular surfaces formed in the upper and lower surfaces of the gas distribution plate such that the contact area of the plasma ion is increased.

5. The apparatus according to claim 2, wherein the ion trap comprises irregular surfaces formed in the upper and lower surfaces of the gas distribution plate such that the contact area of the plasma ion is increased.

6. The apparatus according to claim 2, wherein the DC power applying units apply negative DC power having different sizes to the regions, respectively.

7. The apparatus according to claim 2, wherein the insulator divides the gas distribution plate into a center portion, an edge portion, and a middle portion located between the center and edge portions, and wherein the DC power applying units are provided which comprise a first DC power applying unit for applying a negative DC power to the center portion, a second DC power applying unit for applying a negative DC power to the edge portion, and a third DC power applying unit for applying a negative DC power to the middle portion.

8. The apparatus according to claim 1, which further comprises:
a first gas distribution plate interposed between the process chamber and the plasma chamber and defining a plurality of distribution holes such that the injected plasma is distributed to a plurality of directions within the plasma processing space; and
a second gas distribution plate installed below the first gas distribution plate and defining a plurality of distribution holes such that the plasma passing through the first gas distribution plate is further distributed to a plurality of directions within the plasma processing space.

9. The apparatus according to claim 8, wherein at least one of the first gas distribution plate and the second gas distribution plate is rotatably mounted, and wherein the gas distribution plate which is rotatably mounted is connected to a rotating unit for rotating the rotatably mounted gas distribution plate.

10. The apparatus according to claim 9, wherein the ion trap comprises a DC power applying unit which is connected to at least one of the first gas distribution plate and the second gas distribution plate and applies negative DC power to each connected gas distribution plate.

11. The apparatus according to claim 10, wherein the ion trap comprises irregular surfaces formed in the upper and lower surfaces of the gas distribution plates such that the contact area of the plasma ion is increased.

12. The apparatus according to claim 9, wherein the ion trap comprises DC power applying units and a plurality of insulators which are provided in the gas distribution plates and which divides the gas distribution plates into a plurality of regions which are insulated from each other, respectively.

13. The apparatus according to claim 12, wherein the ion trap comprises irregular surfaces formed in the upper and lower surfaces of the gas distribution plates such that the contact area of the plasma ion is increased.

14. The apparatus according to claim 12, wherein DC power applying units apply negative DC power to the plurality of regions, respectively.

15. The apparatus according to claim 12, wherein the insulators divide the gas distribution plates into center portions, edge portions and middle portions located between the center portions and the edge portions, respectively, and wherein the DC power applying units comprise first DC power applying units for applying a negative DC powers to the center portions, second DC power applying units for applying a negative DC powers to the edge portions, and third DC power applying units for applying a negative DC powers to the middle portions.

16. The apparatus according to claim 8, wherein at least one of the first gas distribution plate and the second gas distribution plate is rotatably mounted, and wherein the gas distribution plate which is rotatably mounted is connected to a rotating unit for rotating the rotatably mounted gas distribution plate.

17. The apparatus according to claim 16, wherein the ion trap comprises DC power applying units connected to the respective first and second gas distribution plates and apply negative DC powers thereto, respectively.

18. The apparatus according to claim 16, wherein the ion trap comprises DC power applying units and a plurality of insulators which are provided in the gas distribution plates and which divides the gas distribution plates into a plurality of regions which are insulated from each other, respectively.

19. The apparatus according to claim 18, wherein DC power applying units apply negative DC power to the plurality of regions, respectively.

20. The apparatus according to claim 18, wherein the insulators divide the gas distribution plates into center portions, edge portions and middle portions located between the center portions and the edge portions, and wherein the DC power applying units comprise first DC power applying units for applying a negative DC powers to the center portions, second DC power applying units for applying a negative DC powers to the edge portions, and third DC power applying units for applying a negative DC powers to the middle portions.
